(19) United States
(12) Patent Application Publication
(10) Pub. No.: US 2011/0011634 A1
(43) Pub. Date: Jan. 20, 2011

(54) CIRCUIT PACKAGE WITH INTEGRATED DIRECT-CURRENT (DC) BLOCKING CAPACITOR

(75) Inventors: Peter Moldauer, Wellington, CO (US); Nicole A. Butel, Fort Collins, CO (US); Brian James Misek, Fort Collins, CO (US)

Correspondence Address: Kathy Manke;Avago Technologies Limited, 4380 Ziegler Road, Fort Collins, CO, 80525, US

(73) Assignee: Avago Technologies Enterprise IP (Singapore )Pte. Ltd., Singapore (SG)

(21) Appl. No.: 12/502,243

(22) Filed: Jul. 14, 2009

(51) Int. Cl. H05K 1/16; H05K 1/11; H05K 3/30

(52) U.S. Cl. 174/260; 174/262; 29/837

(57) ABSTRACT

A circuit package includes a substrate formed using a plurality of layers, the substrate having a first surface and a second surface, at least some of the plurality of layers being electrically interconnected by a via; and at least one standard surface-mount capacitive element electrically coupled to at least one surface of the substrate, thereby allowing electrical and mechanical access to the first surface and the second surface, the at least one standard surface-mount capacitive element located to prevent the passage of a direct current (DC) signal through the circuit package.

### BACKGROUND

As integrated circuits become increasingly compact, operating frequencies continue to increase and processing dimensions continue to shrink. One of the ways that a signal propagates through a circuit is known as a “via.” A via is an interconnecting electrical path that allows a signal to traverse the different layers of a printed circuit board (PCB) or circuit card. Generally, a via is formed by drilling a hole through the circuit substrate, and then plating the resultant hole to create what is referred to as a plated through hole (PTH), thereby creating an electrically conductive path within the PCB. The plating may extend to the surface or surfaces of the circuit substrate. Typically, with high-speed circuits, the signals are routed through the internal layers of a multi-layer PCB. As an example, a receive signal is typically passed through a surface-mounted direct current (DC) blocking capacitor to remove the unwanted DC signal component. However, portions of a via that may not be used for signal routing are still electrically coupled to the signal.

FIG. 1 is a schematic diagram illustrating a prior art circuit assembly 1. The circuit assembly generally includes a printed circuit board (PCB) 2 (also sometimes referred to as a printed wiring board (PWB), on which is mounted an integrated circuit (IC) package 20. In an embodiment, the package 20 includes, or is otherwise assembled to an “integrated circuit” 26, also referred to as a “chip” or an “IC chip.” Typically, the chip 26 contains the active circuitry and the package 20 functions as an interface between the chip 26 and the PCB 2. Generally, the package 20 is electrically and mechanically connected to the PCB 2 using conductive elements 22, which can be conductive balls, an exemplary one of which is illustrated using reference numeral 22. Similarly, the chip 26 is connected to the package 20 using conductive elements 24, such as, solder balls or pillars. The package 20 includes partial vias 23 and 27 that are electrically coupled through conductive trace 28.

One or more portions of the PCB 2 may include one or more vias, schematically shown using reference numerals 6, 8, 32 and 34. The term “via” is used to define an interconnect structure that typically electrically couples different layers in a circuit structure. A via may also be thought of as a structure or a conductor that carries a signal and which may be connected to a signal line or a signal trace. A via may be a structure that passes completely through the PCB 2, in which case it is referred to as a through via, or may be a structure that passes partially through the PCB 2, in which case it is referred to as a “built-up,” a “partial through via,” a “blind via” or a “buried via.” The via may also be a micro-via, created using a laser drill or another process, having a diameter on the order of less than about 100 micrometers (μm). The via 6 is coupled to a conductive pad 5 and the via 8 is coupled to a conductive pad 7. A capacitor 13, which can function as a DC blocking capacitor, is located on the PCB 2, and is electrically coupled to signal conductors 12 and 17 using vias 32 and 34.

The portions 16, 36, 38 and 18 of the vias 6, 32, 34 and 8, respectively, are referred to as a “stub” portions because the signal path traverses from conductive pad 5, down via 6, across the conductive trace 12, up via 32, across capacitor 13, down via 34, across conductive trace 17 and up via 8 to conductive pad 7, so that the stub portions 16, 36, 38 and 18 of vias 6, 32, 34 and 8, respectively, are not part of the signal path. The stub portions 16, 36, 38 and 18 are electrically unused parts of their respective vias and can contribute to detrimental coupling, or other detrimental conditions. For example, the via stub portions may resonate at multiples of the signal frequency, or may function as open-ended transmission lines, thus leading to signal reflection, cross-talk, or other detrimental effects.

Therefore, it would be desirable to have a way to minimize the number of vias in a circuit.

### SUMMARY

In an embodiment, a circuit package, comprises a substrate formed using a plurality of layers, the substrate having a first surface and a second surface, at least some of the plurality of layers being electrically interconnected by a via; and at least one standard surface-mount capacitive element electrically coupled to at least one surface of the substrate, thereby allowing electrical and mechanical access to the first surface and the second surface, the at least one standard surface-mount capacitive element located to prevent the passage of a direct current (DC) signal through the circuit package.

### BRIEF DESCRIPTION OF THE DRAWINGS

The invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1 is a schematic diagram illustrating a prior art circuit assembly.

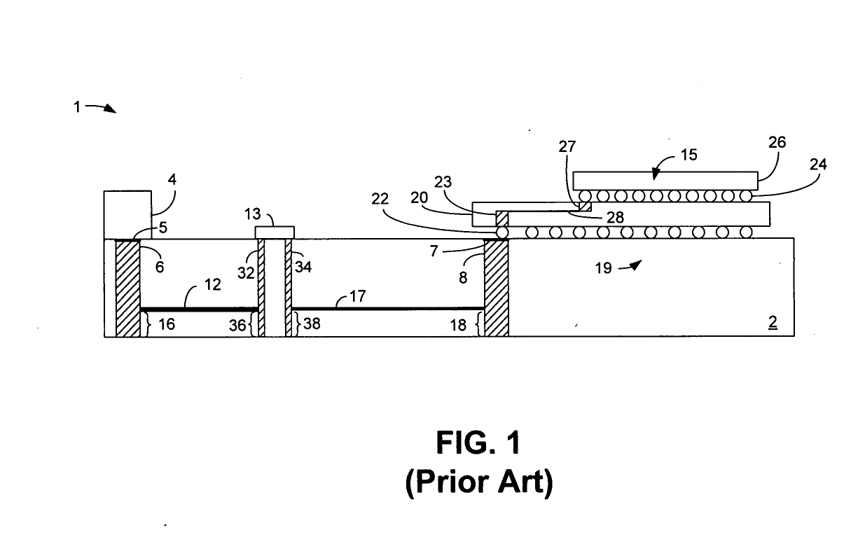

FIG. 2 is a schematic diagram illustrating a portion of an integrated circuit (IC) package.

FIG. 3 is a top plan view illustrating a portion of the package of FIG. 2.

### DETAILED DESCRIPTION

Embodiments of the circuit package with integrated direct current (DC) blocking capacitor are implemented in an integrated circuit architecture to allow the DC blocking capacitor to be located on, or otherwise associated with, the circuit package to reduce the number of via assemblies on the associated circuit board. Further, the circuit package with integrated DC blocking capacitor to be described below can be implemented on an integrated circuit (IC) package using standard and widely available surface-mount capacitive components, while preserving access to both active surfaces of the IC package.

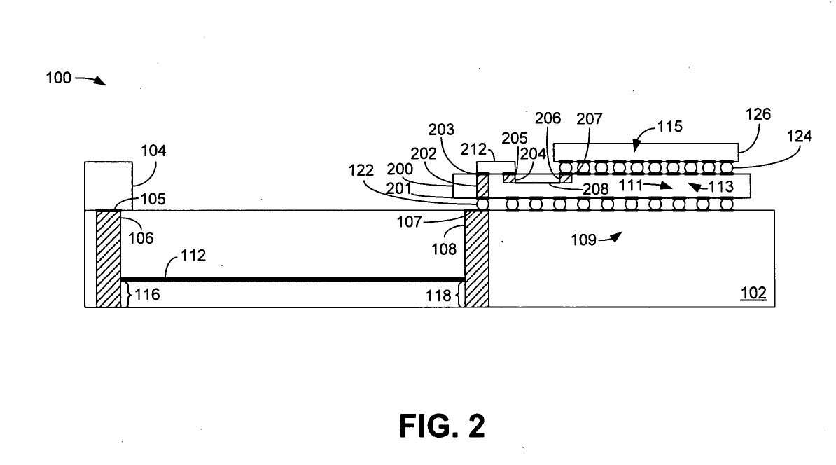

FIG. 2 is a schematic diagram illustrating a circuit assembly 100. The circuit assembly 100 generally includes a printed circuit board (PCB) 102 (also sometimes referred to as a printed wiring board (PWB)), on which an integrated circuit (IC) package 200 is mounted. In an embodiment, the package 200 includes, or is otherwise assembled to an “integrated circuit” 126, also referred to as a “chip” or an “IC chip.” Typically, the chip 126 contains the active circuitry and the package 200 functions as an interface between the chip 126 and the PCB 102. In an embodiment, and not specifically limited to the examples described, the package 200 is electrically and mechanically connected to the PCB 102 using conductive elements 122. In an embodiment in which the package 200 couples to other electrical components via a ball grid array, (BGA), conductive balls, an exemplary one of which is illustrated using reference numeral 122, are located between conductive portions of the package 200 and conductive portions of the surface of the PCB 102. In an embodiment, the conductive element 122 is a solder ball and is connected to conductive pads 109 on the PCB 102 and to conductive pads 111 on the package 200. Similarly, the chip 126 is connected to the package 200 using conductive elements 124, such as, but not limited to, solder balls or pillars, that are connected to conductive pads 113 on the package 200 and conductive pads 115 on the chip 126.

One or more portions of the PCB 102 may include one or more vias, schematically shown using reference numerals 106 and 108. The term “via” is used to define an interconnect structure that typically electrically couples different layers in a circuit structure. A via may also be thought of as a structure or a conductor that carries a signal and which may be connected to a signal line or a signal trace. A via may be a structure that passes completely through the PCB 102, in which case it is referred to as a through via, or may be a structure that passes partially through the PCB 102, in which case it is referred to as a “partial via,” a “built-up via,” a “partial through via,” a “blind via” or a “buried via.” The via may also be a micro-via, created using a laser drill or another process, having a diameter on the order of less than about 100 micrometers (μm). The via 106 is coupled to a conductive pad 105 and the via 108 is coupled to a conductive pad 107. The conductive pads 105 and 107 allow the vias 106 and 108, respectively, to be electrically and mechanically coupled to circuit elements on a surface of the PCB 102.

In an embodiment, the via 106 is coupled to a connector 104 through the conductive pad 105, and to the via 108 through a conductive trace 112. The via 108 is electrically coupled to the conductive element 122 through the conductive pad 107.

In an embodiment, the package 200 can be a multi-layer structure that may include a through via 202 and partial vias 204 and 206. The partial vias 204 and 206 are electrically coupled together using a conductor 208. In an embodiment, the conductor 208 can be a conductive trace formed in the package 200 using known techniques, or can be any other electrically conductive connection.

In an embodiment in accordance with the circuit package with integrated DC blocking capacitor, the through via 202 is electrically coupled to a standard surface-mount capacitive element, such as a capacitor 212, through a conductive pad 203. The opposite terminal of the capacitor 212 is coupled to the partial via 204 through the conductive pad 205. The partial via 206 is coupled to the chip 126 through the conductive pad 207 and the conductive element 124. In this manner, the package 200 includes the DC blocking capacitor 212 integrated thereon, thereby reducing the number of through vias 106 and 108, and the resultant via stub portions, that would otherwise be required on the PCB 102.

In the embodiment shown in FIG. 2, the signal path traverses from conductive pad 105, down via 106, across the conductive trace 112, up via 108 to conductive pad 107. By locating the DC blocking capacitor 212 on the package 200, the structure described in FIG. 2 eliminates at least two of the via stubs that would otherwise be present on the PCB 102 if the DC blocking capacitor 212 were located on the PCB 102. In this manner, detrimental effects caused by via stubs are reduced because the number of via stubs are reduced.

Locating the DC blocking capacitor 212 on the package 200 and away from the PCB 102 also eliminates the need for a separate additional conductor through the PCB 102 to make electrical contact to the DC blocking capacitor 212. Eliminating a conductor within the PCB 102 to connect to the DC blocking capacitor 212 decreases the cost of the circuit assembly because it is quite costly to have conductors in the PCB that avoid the circuit paths, such as conductive trace 112. The cost associated with locating the DC blocking capacitor 212 on the package 200 is comparable to the cost of locating the DC blocking capacitor 212 on the PWB 102, but significantly reduces any signal degradation that would otherwise be caused by having conductors to the DC blocking capacitor 212 on or in the PWB 102. Having the vias 108, 202 and 204 electrically couple the DC blocking capacitor 212 to the chip 126 substantially eliminates any conductors in the signal path (in the PWB 102), while minimizing assembly cost.

Further, as will be described in greater detail below, the structure of the package 200 allows access to both major surfaces of the package 200, while locating the capacitor 212 on the package 200 to prevent the passage of a direct current (DC) signal through the package 200 to the chip 126. In this manner, the capacitor 212 can be located on either major surface of the package 200.

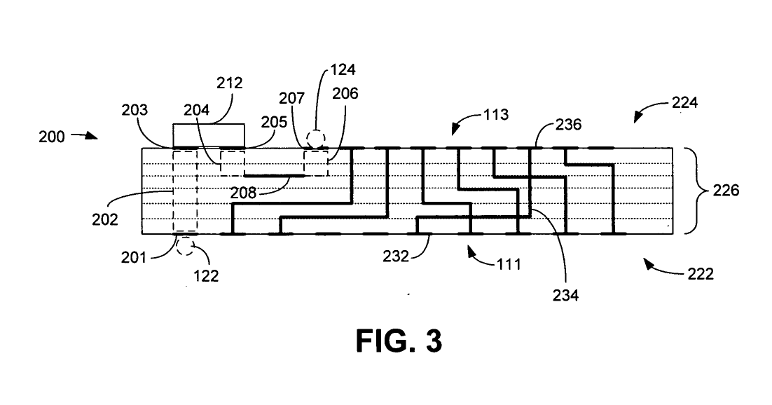

FIG. 3 is a cross-sectional schematic diagram illustrating an embodiment of the package 200 of FIG. 2. The package 200 comprises a multilayer structure 226. The multi-layer structure 226 can be formed by conventional circuit processing and assembly techniques. The structure of the package 200 can be similar to the structure of the PCB 102, in that one or more conductive layers can be separated by non-conductive layers and structural layers, to form a laminate structure. However, other structures, such as homogeneous material layers, and other non-laminate structures, are possible.

The package 200 includes a first surface 222 and a second surface 224. The first surface 222 and the second surface 224 are referred to as the major surfaces of the package 200. The first surface 222 includes the plurality of conductive pads 111, and the second surface 224 includes the conductive pads 113. For exemplary purposes only, a conductive pad 232 on the first surface 222 is electrically coupled through a connection 234 to a conductive pad 236 on the second surface 224. In this manner, and generally speaking, an electrical signal is passed through the package 200 from the first surface 222 to the second surface 224. Further, although the capacitor 212 is shown as being located on the second surface 224, the capacitor 212 can alternatively be located on the first surface 222. Further capacitors can be located on both the first surface 222 and the second surface 224. By having access to both major surfaces 222 and 224, the capacitor 212 can be releasably located on either or both surfaces 222 and 224.

In accordance with an embodiment of the circuit package with integrated DC blocking capacitor, the package 200 includes a through via 202 and partial vias 204 and 206. As described above, the through via 202 is coupled through a conductive pad 203 to a first terminal of a capacitor 212. A second terminal of the capacitor 212 is coupled through a conductive pad 205 to the partial via 204. The partial via 204 is electrically coupled via conductor 208 to a partial via 206. The partial via 206 is electrically coupled through a conductive pad 207 to a conductive element 124, as described above. The conductive elements 122 and 124 are shown in FIG. 3 in dotted line for reference. In this manner, a DC blocking capacitor, such as the standard capacitor 212 can be located on the circuit package 200, while allowing complete access to the conductive portions of the first surface 222 and the second surface 224 of the package 200.

This disclosure describes the invention in detail using illustrative embodiments. However, it is to be understood that the invention defined by the appended claims is not limited to the precise embodiments described.

What is claimed is:

1. A circuit package, comprising:
a substrate formed using a plurality of layers, the substrate having a first surface and a second surface, at least some of the plurality of layers being electrically interconnected by a via; and
at least one standard surface-mount capacitive element electrically coupled to at least one surface of the substrate, thereby allowing electrical and mechanical access to the first surface and the second surface, the at least one standard surface-mount capacitive element located to prevent the passage of a direct current (DC) signal through the circuit package.

2. The circuit package of claim 1, wherein the via extends completely through the substrate.

3. The circuit package of claim 1, wherein the via extends partially through the substrate.

4. The circuit package of claim 1, wherein the standard surface-mount capacitive element is releasably coupled to the at least one surface of the substrate.

5. The circuit package of claim 1, wherein the standard surface-mount capacitive element is electrically coupled to a through via and to a partial via.

6. A circuit assembly, comprising:
a printed circuit board;
a circuit package electrically coupled to the printed circuit board, the circuit package comprising:
a substrate formed using a plurality of layers, the substrate having a first surface and a second surface, at least some of the plurality of layers being electrically interconnected by a via; and
at least one standard surface-mount capacitive element electrically coupled to at least one surface of the substrate, thereby allowing electrical and mechanical access to the first surface and the second surface, the at least one standard surface-mount capacitive element located to prevent the passage of a direct current (DC) signal through the circuit package; and
an integrated circuit electrically coupled to the circuit package.

7. The circuit assembly of claim 6, wherein the via extends completely through the substrate.

8. The circuit assembly of claim 6, wherein the via extends partially through the substrate.

9. The circuit assembly of claim 6, wherein the standard surface-mount capacitive element is releasably coupled to the at least one surface of the substrate.

10. The circuit assembly of claim 6, wherein the standard surface-mount capacitive element is electrically coupled to a through via and to a partial via.

11. A method for making a circuit package, comprising:
forming a substrate using a plurality of layers, the substrate having a first surface and a second surface, at least some of the plurality of layers being electrically interconnected by a via; and
coupling electrically at least one standard surface-mount capacitive element to at least one surface of the substrate, thereby allowing electrical and mechanical access to the first surface and the second surface, the at least one standard surface-mount capacitive element located to prevent the passage of a direct current (DC) signal through the circuit package.

12. The method of claim 11, wherein the via extends completely through the substrate.

13. The method of claim 11, wherein the via extends partially through the substrate.

14. The method of claim 11, further comprising releasably coupling the standard surface-mount capacitive element to the at least one surface of the substrate.

15. The method of claim 11, wherein the standard surface-mount capacitive element is electrically coupled to a through via and to a partial via.
